(19) United States
(12) Patent Application Publication
(10) Pub. No.: US 2013/0048488 A1
(43) Pub. Date: Feb. 28, 2013

(54) Impermeable PVD Target Coating for Porous Target Materials

(71) Applicant: Paul Shufflebotham, San Jose, CA (US)

(72) Inventor: Paul Shufflebotham, San Jose, CA (US)

(73) Assignee: MiaSole

(21) Appl. No.: 13/219,832

(22) Filed: Aug. 29, 2011

(51) Int. Cl. C23C 14/34; B05D 1/36; H01L 31/18; B05D 5/00; B05D 3/02; C23C 14/06; B05D 1/38

(52) U.S. Cl. 204/192.1; 204/298.02; 204/298.13; 427/402; 427/404; 427/407.1; 427/154; 427/372.2; 438/84; 257/E31.027

(57) ABSTRACT

A method of making a sputtering target includes forming a sputtering target containing a relatively porous sputtering material. The sputtering material may be initially formed to be substantially free of water or treated to remove substantially all of absorbed or adsorbed water from the sputtering material. The method also includes forming a water impermeable barrier layer over the substantially water free sputtering material to completely or substantially prevent re-absorption or re-adsorption of water in the sputtering material.

### BACKGROUND

The present invention is directed generally to sputtering targets and methods of making and using thereof and specifically to a sputtering target having a protective coating on its surface that is impermeable to water, oils, solvents and other chemical contaminants and methods of making and using thereof.

Sputtering is used in a number of applications, including forming conductive (e.g., metal), insulating (e.g., silicon oxide or metal oxide) and/or semiconductor layers in solid state devices, such as semiconductor devices. Examples of semiconductor devices include memory devices, logic devices, photovoltaic devices (e.g., solar cells), photodetectors, light emitting devices (e.g., lasers), etc.

For example, a typical thin-film solar cell may include a substrate, a first electrode, at least one semiconductor absorber layer of one conductivity type, at least one semiconductor window layer of the opposite conductivity type and a second electrode. One or more layers of the solar cell may be formed by sputtering. For example, all of the above layers may be formed by sputtering as described in U.S. Published Application No. 2005/0109392 A1 (“Hollars”).

The first electrode may be a transition metal layer, such as molybdenum, that is deposited using a sputtering process. For example, the first electrode may be formed by sputtering a sodium-containing molybdenum (e.g., molybdenum (Mo) doped with sodium and/or oxygen (Na) or “MoNa”) target.

The semiconductor material may include any suitable material, such as copper indium gallium selenide (CIGS), CdTe, Si, Ge, SiGe, GaAs, GaN, etc. For example, the semiconductor absorber layer may be a p-type layer CIS based alloy deposited by sputtering. Copper indium diselenide (CuInSe₂, or CIS) and its higher band gap variants copper indium gallium diselenide (Cu(In,Ga)Se₂, or CIGS), copper indium aluminum diselenide (Cu(In,Al)Se₂), copper indium gallium aluminum diselenide (Cu(In,Ga,Al)Se₂) and any of these compounds with sulfur replacing some of the selenium represent a group of materials, referred to as copper indium selenide CIS based alloys, have desirable properties for use as the absorber layer in thin-film solar cells. To function as a solar absorber layer, these materials should be p-type semiconductors.

Before a sputtering target is used in the sputtering process, the target typically undergoes a bake out and a burn-in process that removes impurities from the surface of the target. A burn-in process may take several hours to perform.

Coatings may be applied to the surface of a metal target to make the target surface non-reactive (i.e., non-oxide forming). For example, a target made of aluminum or titanium for memory or logic device electrode fabrication may quickly react with oxygen to produce an undesirable native oxide layer. In cases where this oxide layer may interfere with the electrode sputtering process, the oxide layer is removed prior to sputtering and the target is coated with a passivation layer or placed in a metal enclosure that prevents the formation of a native metal oxide layer on the sputtering material surface, as described in U.S. Pat. No. 6,030,514, incorporated herein by reference.

In contrast, metal oxide targets (for example molybdenum oxide, aluminum oxide, titanium oxides, etc.) are not susceptible to harmful surface oxidation since they are already composed of a metal oxide throughout their thickness. Furthermore, certain metal (i.e., pure metal or metal alloy) targets (e.g., indium, etc.) resist oxidation at room temperature or oxidize very slowly (e.g., copper, etc.). Thus, a passivation layer or metal enclosure is generally not used on the surface of the metal oxide or oxidation resistant metal targets because these targets do not oxidize in air or oxidize very slowly during transport between their manufacturing chamber and the sputter deposition chamber.

### SUMMARY

An embodiment provides a method of making a sputtering target which includes a method of making a sputtering target, comprising forming a sputtering target comprising a sputtering material that is substantially free of all of at least one of absorbed or adsorbed water, and forming a water impermeable barrier layer over the sputtering material to completely or substantially prevent at least one of re-absorption or re-adsorption of water to the sputtering material.

Another embodiment provides a method of using a sputtering target, comprising providing a sputtering target comprising a sputtering material having substantially no absorbed or adsorbed water in the sputtering material and comprising a water impermeable barrier layer over the sputtering material, removing the barrier layer, and providing the sputtering target into a sputtering chamber such that the sputtering material in the sputtering chamber is completely or substantially water free.

Another embodiment provides a sputtering target, comprising a sputtering material having substantially no absorbed or adsorbed water in the sputtering material and a water impermeable barrier layer over the sputtering material having a higher density than the sputtering material.

### DESCRIPTION OF THE DRAWINGS

FIG. 1 is a schematic side cross sectional view of a prior art porous planar target in which water has been absorbed and adsorbed.

FIG. 2 is a schematic side cross sectional view of a porous planar target with a water impermeable barrier layer according to an embodiment.

FIG. 3 is a schematic side cross sectional view of a porous cylindrical target with a water impermeable barrier layer according to another embodiment.

FIG. 4 is a flow diagram illustrating a process by which a porous target is treated to prevent or decrease water absorption and water adsorption according to an embodiment.

FIG. 5 is a schematic side cross-sectional view of a CIS based solar cell made using the sputtering target according to one embodiment of the invention.

FIG. 6 shows a highly simplified schematic diagram of a top view of a modular sputtering apparatus that includes the sputtering target of FIG. 3 can be used to manufacture the solar cell depicted in FIG. 5.

FIG. 7 illustrates schematically the use of three sets of dual magnetrons to increase the deposition rate and grade the composition of the CIGS layer to vary its band gap.

### DETAILED DESCRIPTION

The present inventor recognized that while metal oxide targets (for example molybdenum oxide, aluminum oxide, titanium oxide, etc.) or room temperature oxidation resistant metal targets (e.g., indium, copper-indium-gallium, copper-indium, etc.) are not susceptible to harmful surface oxidation during transport, these targets may contain adsorbed or absorbed water if these targets are sufficiently porous. A porous metal or metal oxide target, while suitable for use in sputtering applications, may be susceptible to moisture absorption/adsorption during manufacturing or during transport between the target manufacturing and the sputtering (i.e., the end use) chambers. Water is extremely “sticky” and notoriously hard to remove from vacuum systems. When trapped within pores of a porous target material, water can be particularly difficult, expensive and time-consuming to remove from the sputtering chamber even after a lengthy bake out and burn-in processes.

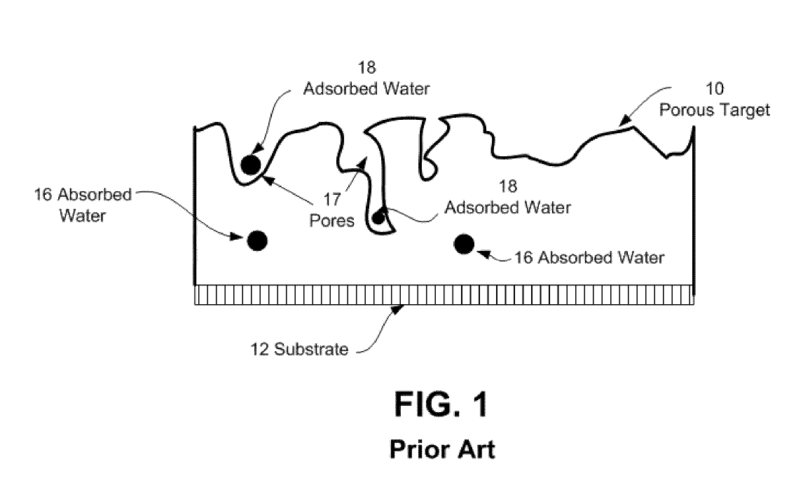

FIG. 1 illustrates a prior art porous planar target 1 a in which water has been absorbed and adsorbed. The relatively porous sputtering material 10 formed on substrate 12 (i.e., backing plate) is shown as having absorbed water 16 trapped in internal pores and adsorbed water 18 fixed to surface pores of the target sputtering material 10. Such relatively porous targets absorb large amounts of moisture from the air or by getting wet. The adsorbed water 18 may be found deep within the porous target material as well. For example, a highly porous target material can have a network of pores 17 that extends deep into the target thickness and greatly increase the surface area available to the adsorbed water 18, as shown in FIG. 1. This absorbed and adsorbed moisture is generally removed during the bake-out process in the vacuum sputtering chamber. Water outgases very slowly (e.g., in hours or even days, even when baked out at high temperature or removed during burn-in at high sputtering powers) thereby significantly prolonging the bake-out and/or burn-in processes.

In one embodiment of the invention, the adsorbed and/or absorbed water is removed from the relatively porous sputtering target prior to installation into the sputtering chamber, followed by forming a water impermeable barrier layer on the surface of the target. These steps are preferably conducted at the manufacturing facility where the target is made. The substantially water free target covered with the barrier layer is then transported to a sputtering system where it will be used and installed in the vacuum sputtering chamber. The barrier layer is then removed in the sputtering chamber during bake out and/or burn-in. Alternatively, the barrier layer is removed in a substantially water free ambient (e.g., nitrogen or noble gas inert ambient) and the substantially water free target is then installed into the vacuum sputtering chamber without exposing the target to an oxidizing ambient (e.g., to air).

As used herein, the term “relatively porous” refers to a sputtering material of the target having a surface and/or volume porosity sufficient to adsorb and/or absorb water, respectively. For example, the relatively porous material may have a surface and/or volume porosity above 2 volume % (e.g., material is less than 98% dense). For example, the surface and/or volume porosity of the sputtering material of the target may comprise 7-25 volume % (e.g., the material is 75% to 93% dense).

In an embodiment, a final processing step of the target fabrication method includes removing substantially all of the water from the sputtering material, such as at least 95%, for example 95 to 99.99% of the adsorbed water by baking or annealing, and then forming one or more layers of water impermeable barrier material over the sputtering material of the target. Alternatively, the process used to form sputtering material may be selected to produce a sputtering material that is initially substantially water free and that does not require removing the water from the sputtering material before forming the barrier layer(s) over the sputtering material. The sputtering material that is substantially water free preferably contains 0.1 or less atomic percent water, such as 0.001 to 0.1 atomic percent water. Preferably, this water impermeable barrier layer seals the sputtering material on the target and totally or substantially prevents water from adsorbing and/or absorbing to the sputtering material of the target. For example, the water impermeable barrier layer may completely prevent water permeation or it may substantially prevent water permeation such that less than 5% of the water that would have been absorbed and/or absorbed to the sputtering material of the target without the water impermeable barrier layer actually absorbs and/or adsorbs to the sputtering material sealed with the water impermeable layer.

The water impermeable barrier layer may comprise any water impermeable material, such as a metal, a ceramic, or a polymer (e.g., plastic) material. Preferably, the water impermeable barrier layer is relatively thin compared to the thickness of the sputtering material, such as having a thickness that is 10 to 1000 times thinner than the thickness of the sputtering material. The barrier layer should be continuous enough to seal off the network of pores 17 in certain embodiments, such as for highly porous target materials.

Preferably, the water impermeable barrier layer is easy to remove and is selectively removable compared to the sputtering material of the target. In other words, the water impermeable barrier layer can be removed from the sputtering material without removing any or substantially any (e.g., 5% or less) of the sputtering material.

In a first embodiment, the water impermeable barrier layer is removed after the target is installed in the sputter deposition vacuum chamber. In one aspect of the first embodiment, the water impermeable barrier layer is a low temperature material which is removed during the bake-out phase of preparing the sputtering apparatus for normal operation. For example, the bake out process is conducted after the pump-purge process where the vacuum sputtering chamber is pumped down to vacuum (e.g., about 10⁻⁶ torr) to drive out contaminates from the ambient. During bake out, the sputtering chamber containing the target is heated to a temperature of 200 C or above, such as 225 to 400 C, using heating lamps and/or resistance heaters in the chamber. The bake out process may be conducted for 1 minute to 6 hours, such as 10 minutes to 45 minutes in vacuum or in an inert gas (e.g., argon, nitrogen, etc.). During the bake out process, the high temperature in the chamber burns off the low temperature water impermeable layer, such as a polymer layer which burns away at or below the bake out temperature. The burned residue of the water impermeable barrier layer (e.g., a gas or vapor) is pumped out during the bake out process by the vacuum pump(s) connected to the sputtering chamber.

In another aspect of the first embodiment, the water impermeable barrier layer is removed from the target during the burn-in process in the sputtering chamber. The burn-in process is conducted after the bake out process and a post bake cool down. In the burn-in process, the sputtering chamber with the sputtering target is operated in a typical plasma ambient (e.g., argon) of the sputtering apparatus at typical operating conditions with a dummy substrate (i.e., a substrate which will not be used in a functional device) to sputter off the barrier layer onto the dummy substrate. If the water impermeable barrier layer is a relatively high temperature material, such as a metal or a ceramic layer that coats the surface of the sputtering material, then this water impermeable barrier layer is sputtered off the target surface during burn-in. The burn-in process may be conducted for 1 minute to 6 hours, such as 10 to 60 minutes.

In another aspect of the first embodiment, the barrier layer is chemically removed in the sputtering chamber using reactive sputtering or dry etching. For example, a polymer barrier layer may be “etched”, “ashed” or “burned off” by an oxidizing ambient, such as an air or oxygen containing gas or plasma during the bake out step, the burn-in step or a separate removal step in addition to the bake out or burn-in step. Alternatively, an oxide barrier layer (e.g., a metal oxide ceramic barrier layer) may be “etched” or “reduced” by a hydrogen containing gas or plasma, such as hydrogen or forming gas or plasma during the bake out step, the burn-in step or a separate removal step in addition to the bake out or burn-in step.

In a second embodiment, the water impermeable barrier layer is removed before installation of the target in the sputtering chamber. For example, the barrier layer is removed in a substantially water free ambient (e.g., nitrogen or noble gas inert ambient) and the substantially water free target is then installed into the vacuum sputtering chamber without exposing the target to an oxidizing ambient. The barrier layer may be removed by etching or ashing (e.g., for organic polymer barrier layers) using dry or wet etching. For example, the target may be provided into a dry etching chamber and subjected to dry etching using an etching gas or plasma (e.g., a halogen or oxygen containing gas or plasma depending on the composition of the barrier layer) which selectively etches the barrier layer compared to the sputtering material to selectively etch off the barrier layer. Alternatively, the target may be provided into a wet etching chamber and subjected to wet etching by being placed in a suitable etching liquid which selectively etches the barrier layer compared to the sputtering material to selectively etch off the barrier layer. The target is then provided from the etching chamber into the sputtering chamber in an inert gas filled envelope or enclosure or in vacuum through a load lock if the etching chamber is part of the same multi-chamber apparatus as the sputtering chamber.

In other alternative aspects of the second embodiment, the barrier layer may be removed by heating, cooling, thermal shock, spraying with dry ice or abrasion in a separate location and then provided into the sputtering chamber without exposing the target to a water containing ambient as described above. For example, polymer materials may be removed by heating in a furnace, cooling in a freezer, thermal shock in a temperature controlled apparatus, or by spraying with dry ice in an inert gas filled chamber. Metal or ceramic barrier layers may be removed by abrasion, such as mounting a cylindrical target on a rotating base, such as in a lathe and removing the barrier layer by contacting it with a tool bit or an abrasive surface, or by using a rotating abrasive pad on a planar or cylindrical target in a water-free ambient.

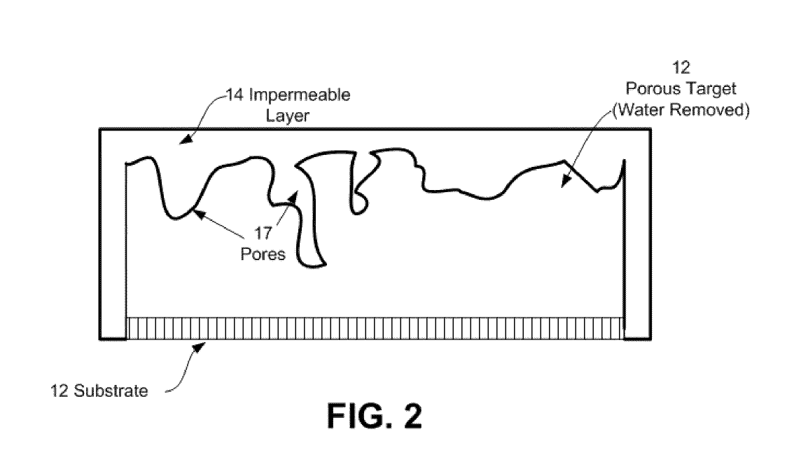

FIG. 2 illustrates a planar sputtering target 1b according to an embodiment. As illustrated in FIG. 2, the porous target is free of water. A water impermeable barrier layer 14 is located on the exposed surfaces of the porous sputtering material 10 located on a backing plate 12 to prevent absorption and adsorption of water before the target is used in a sputtering process.

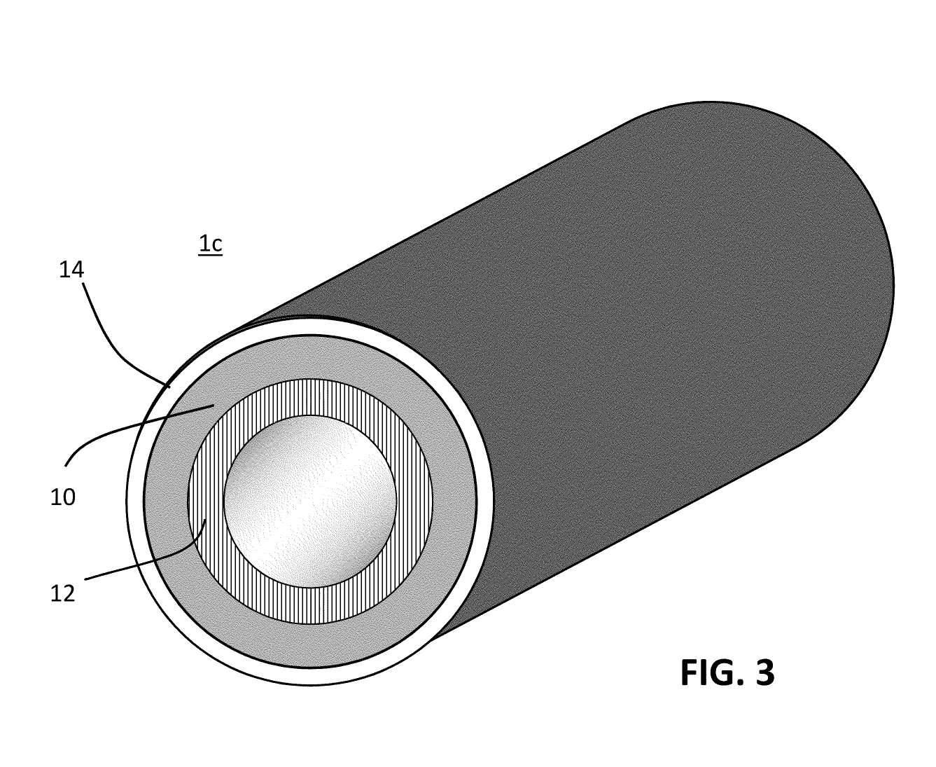

FIG. 3 illustrates a hollow cylindrical sputtering target 1c according to another embodiment. The sputtering target may be a cylindrical shell 10 of sputtering material formed on a cylindrical sputtering target support 12 (e.g., a backing tube, such as a stainless steel, titanium, aluminum or other non-magnetic backing tube). Alternatively, the target may comprise a hollow cylinder or hollow rings 10 made without the backing tube 12. The cylinder or rings may be made in a mold or on a temporary support and then attached to the backing tube which houses the magnet(s), as described for example in U.S. patent application Ser. No. 12/588,578, filed on Oct. 20, 2009, and incorporated herein by reference in its entirety. The barrier layer 14 is located around the outer surface of the sputtering material 10 (and may also be optionally located on the top and bottom edge surfaces of material 10 at the bases of the cylinder 1c). One or more additional optional metal layers may be provided between the backing tube 12 and the sputtering material 10, such as one or more of Cr, Mo/or Nb layers, as described in U.S. Pat. No. 7,785,921, incorporated herein by reference in its entirety for a teaching of these layer(s).

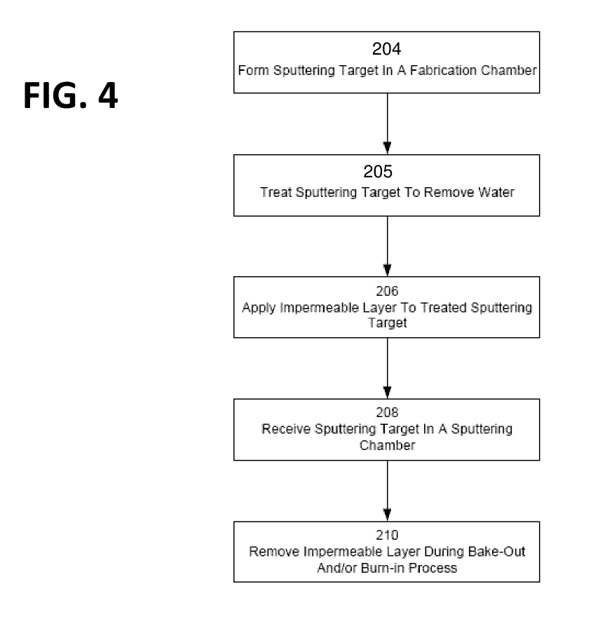

FIG. 4 is a flow diagram illustrating a process by which a porous target is treated to prevent water absorption and water adsorption so as to shorten a bake-out and/or burn-in processes according to an embodiment.

A sputtering target is formed in a fabrication chamber (Block 204). In an embodiment, the target material 10 is formed on the backing tube or plate 12 by any suitable method, such as powder metallurgy (i.e., applying a metal powder to the backing tube or plate followed by pressing and heating the powder), casting, plasma spray, injection molding, twin arc wire spraying (TWAS), or any other suitable technique described in U.S. patent application Ser. No. 12/588,578 filed on Oct. 20, 2009 and incorporated herein by reference in its entirety for a teaching of target fabrication techniques.

Plasma spraying involves generating a plasma by excitation of an inert gas passing through an electric arc, creating a very hot ionized gas. A sputtering material 10 in powder form, such as MoNa, is injected into the gas stream where it becomes molten and accelerated onto a substrate 12. The sputtering material 10 is built up layer by layer through intra-particle bonding and sintering reactions. The targets that are produced in this manner may be very porous, which allows water absorption and adsorption.

Examples of casting processes (e.g., dip casting, vacuum mold casting, semi-solid casting, direct strip casting, centrifugal casting, continuous casting, squeeze casting, etc.) and injection molding processes are described in U.S. application Ser. No. 12/588,578, filed on Oct. 20, 2009, and incorporated herein by reference in its entirety for a teaching of these methods. In the casting and injection molding processes, the copper, indium and gallium containing compound may be combined at a temperature high enough to form a liquid melt. The liquid is then solidified onto the target support which may be located in a mold or in other suitable casting or molding liquid receiving positions to form a CIG sputtering material 10 on the backing plate or tube 12.

Alternatively, the copper, indium and gallium may be combined at a temperature suitable for forming a thixotropic slurry. Thixotropic metal melts as used herein are those in which the viscosity of the melt is lowered by mixing as the melt cools. Instead of forming interlocking dendrites on cooling, the precipitating solids have a more rounded, spheroidal shape allowing the melt to flow even at temperatures at which it would otherwise be semisolid. In one aspect, the copper, indium and gallium are combined at an appropriate thixotropic temperature in a container (e.g., melting chamber or melting pot). Preferably, the thixotropic slurry is stirred by a stirrer or fin located in the chamber or pot prior to casting or injection molding.

Further, as discussed above, the sputtering target may be either formed on a target support or a hollow cylinder or ring made without a backing tube. Thus, embodiments of the present invention include casting and injection molding both supported sputtering targets (i.e., cast or molded onto the backing tube) and unsupported targets (not cast or molded with the backing tube as part of the casting mold).

As with the casting and injection molding embodiments, the TWAS method may be used to form both supported sputtering targets and unsupported. Additionally, the TWAS method may use compound wires. That is, wires that have a distinct core and shell made of different materials.

Powder metallurgy processes include both hot pressing and cold pressing. In either process, the starting material may be powders of the individual copper, indium and gallium elements. However, gallium is a liquid at room temperature. Therefore, the starting materials may preferably include alloys of gallium such as InGa, CuGa, and CuInGa (i.e., a copper, indium and gallium alloy). In another example, a copper powder, indium powder and copper-gallium alloy powder may be mixed together, preferably under the above described control atmosphere.

The starting materials may be mixed in the desired ratios and then pressed to form an unsupported sputtering target (i.e., pressed onto a temporary support and then attached to the backing tube) or pressed onto a sputtering support (e.g., backing tube). The pressing may be warm or cold, uniaxial or isostatic.

The fabricated sputtering target is then optionally treated to remove water (Block 205). In an embodiment, any water that may be entrapped in the pores or on the surface of the sputtering material 10 is removed by heating the target to a temperature below the melting point of the sputtering material 10, such as a temperature of 200-400 C for 5 minutes to 5 hours. The sputtering material 10 preferably contains 0.1 or less atomic percent water after the heating step. The target may be heated in the same chamber as where the sputtering material 10 is deposited on the backing tube or plate 12, or in a separate chamber. Alternatively, the initial sputtering material 10 may be manufactured substantially water free, in which case the water removal step may be omitted.

An impermeable barrier layer 14 is then applied to seal the surface of the target sputtering material 10 before the material 10 is exposed to a water containing ambient (Block 206). For example, the impermeable barrier layer 14 is applied to seal the surface of the target sputtering material 10 before the material 10 is exposed to an ambient that increases the moisture content of the sputtering material by more than 10% of its fully saturated water weight. In other words, the barrier layer is applied to the sputtering material before the sputtering material absorbs or adsorbs more than 10 weight percent of water that the sputtering material is capable of absorbing or adsorbing. For example, the barrier layer 14 may be 2-100 micron thick molybdenum layer on a sodium containing molybdenum oxide (e.g., sodium molybdate or MoNa) sputtering material 10. The impermeable barrier layer 14 acts as a barrier to water absorption and absorption and to contaminants and remains on the target until it is removed. Preferably, the barrier layer 14 is denser than the sputtering material 10. For example, the barrier layer may have a porosity of 2% or less, 0.1 to 2% (i.e., greater than 98% dense). The barrier layer 14 may be formed using the same methods as those described above for the sputtering material 10 or by any other suitable method. The barrier layer 14 may be deposited in the same or a different chamber as where the sputtering material 10 was deposited on the backing tube or plate 12.

The target is then received in the sputtering chamber (Block 208). In an embodiment, the impermeable barrier layer is removed from the target while in the sputtering chamber (Block 210). The layer could be removed in-situ during bake out by heating or during burn-in by sputtering or reactive sputtering as described above.

Alternatively, as described above, the barrier layer 14 may be removed before being placed into the sputtering chamber. For example, the sputtering material 10 is not exposed to an ambient that increases the moisture content of the sputtering material by more than 10% of its fully saturated water weight between removal of the barrier layer and placement of the target into the sputtering chamber. In other words, the sputtering material absorbs or adsorbs less than 10 weight percent of water (e.g., 0-10%) that the sputtering material is capable of absorbing or adsorbing between the steps of removing the barrier layer and placing the target into the sputtering chamber. Thus, the target may be transported in vacuum or inert gas between barrier layer removal and placement into the sputtering chamber or the target may be briefly exposed to water containing ambient without deleteriously affecting the water content of the sputtering material.

Because the impermeable barrier layer protected the target from water absorption and adsorption, the target is virtually water free and the bake-out and/or burn-in processes are substantially shortened. By way of illustration and not by way of limitation, the time for removal of the impermeable barrier layer made from Mo may range from a few minutes to an hour, but it is substantially less than the time for removal of water molecules from the pores of the untreated target. The barrier layer 14 also keeps contaminants, such as oil, fingerprints, dust, solvents and other chemical contaminants out of the sputtering material 10.

The method and target described above may have any suitable composition and may be used to deposit layers in any suitable device. For example, the target may comprise a copper, aluminum or titanium sputtering material used to sputter metal electrodes and interconnects in semiconductor logic or memory devices, such as transistor based logic or DRAM or EEPROM type memory devices, photo detector devices or light emitting devices. Preferably, the method and target are used to deposit one or more layers in a photovoltaic device (e.g., solar cell), as will be described below.

In one embodiment, the target 1 c comprises a sodium molybdate sputtering material 10 used to make a lower electrode of a solar cell as will be described below. This material 10 is a molybdenum based alloy which includes sodium and a lattice distortion element or compound selected from the group consisting of oxygen, MoO₂ and MoO₃. Preferably, the sputtering material comprises at least 59 atomic percent molybdenum (such as 60-95 at %), 1 to 40 atomic percent oxygen (such as 5-10 at %) and 0.01 to 1.5 atomic percent sodium. As noted above, the preferred barrier layer 14 for this sputtering material 10 is a molybdenum layer which is denser than the sputtering material 10. Alternatively, a polymer or ceramic barrier layer 14 may be used.

In another embodiment, the sputtering target may comprise a copper, copper indium, copper-gallium or copper-indium-gallium (CIG) sputtering material 10 that is used for reactive sputtering of a CIGS absorber layer of the solar cell as will be described below. The CIG sputtering material 10 of the target, for example, may have a composition of about 29-41 wt % copper, including 29-39 wt % Cu, about 36-62 wt % indium, including 49-62 wt % In, about 8-25 wt % gallium, including 8-16 wt % Ga. For this sputtering material, the barrier layer 14 located over the sputtering material may comprise a copper, copper-indium or indium layer which is denser than the sputtering material 10. For example, the barrier layer 14 may be a 2-100 micron thick copper layer that is at least 98% dense located on the CIG sputtering material 10 which is less than 98% dense. Alternatively, molybdenum, polymer or ceramic layers may be used instead.

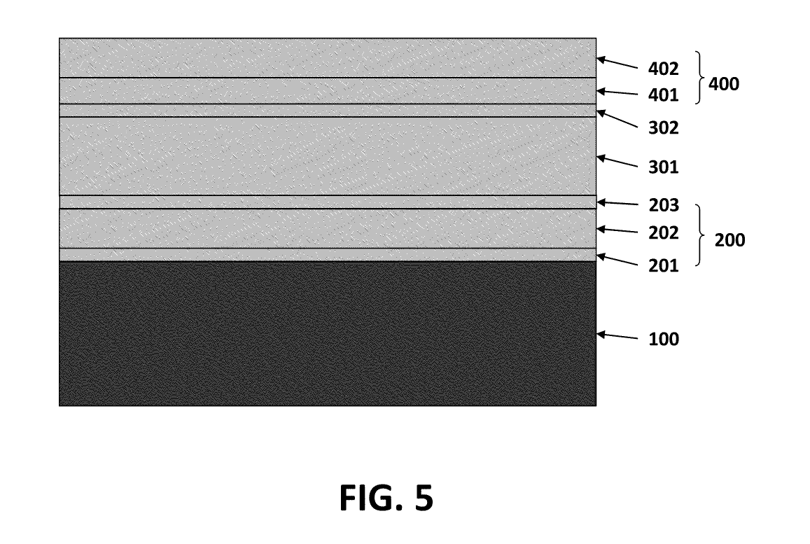

The solar cell made using the MoNa and/or CIG targets described above is illustrated in FIG. 5. The solar cell contains the substrate 100 and a first (lower) electrode 200. Optionally, the first electrode 200 of the solar cell may comprise one or more barrier layers 201 located under the alkali-containing transition metal layer 202, and/or one or more adhesion layers 203 located over the alkali-containing transition metal layer 202. In some embodiments, the barrier layer 201 is denser than the adhesion layer 203, and substantially prevents alkali diffusion from the alkali-containing transition metal layer 202 into the substrate 100. In these embodiments, alkali may diffuse from the alkali-containing transition metal layer 202, through the lower density adhesion layer 203, into the at least one p-type semiconductor absorber layer 301 during and/or after the step of depositing the at least one p-type semiconductor absorber layer 301. The optional barrier layer 201 and adhesion layer 203 may comprise any suitable materials. For example, they may be independently selected from a group consisting of Mo, W, Ta, V, Ti, Nb, Zr, Cr, TiN, ZrN, TaN, VN, V₂N or combinations thereof. In one embodiment, while the barrier layer 201 may be oxygen free, the alkali-containing transition metal layer 202 and/or the adhesion layer 203 may contain oxygen and/or be deposited at a higher pressure than the barrier layer 201 to achieve a lower density than the barrier layer 201. For example, layer 202 may optionally contain 5 to 40 atomic percent oxygen and layer 203 may optionally contain 1 to 10 atomic percent oxygen.

In preferred embodiments, the p-type semiconductor absorber layer 301 may comprise a CIS based alloy material selected from copper indium selenide, copper indium gallium selenide, copper indium aluminum selenide, or combinations thereof. Layer 301 may have a stoichiometric composition having a Group I to Group III to Group VI atomic ratio of about 1:1:2, or a non-stoichiometric composition having an atomic ratio of other than about 1:1:2. Preferably, layer 301 is slightly copper deficient and has a slightly less than one copper atom for each one of Group III atom and each two of Group VI atoms. The step of depositing the at least one p-type semiconductor absorber layer may comprise reactively AC sputtering the semiconductor absorber layer from at least two electrically conductive targets in a sputtering atmosphere that comprises argon gas and a selenium containing gas (e.g. selenium vapor or hydrogen selenide). For example, each of the at least two electrically conductive targets comprises copper, indium and gallium; and the CIS based alloy material comprises copper indium gallium diselenide. In one embodiment, the p-type semiconductor absorber layer 301 may comprise 0.005 to 1.5 atomic percent sodium, such as 0.005 to 0.4 atomic percent sodium diffused from the first transition metal layer 202. As described above, sodium impurities may diffuse from the first transition metal layer 202 to the CIS based alloy layer 301. In one embodiment, the sodium impurities may concentrate at the grain boundaries of CIS based alloy, and may have a concentration as high as 10¹⁹ to 10²² atoms/cm³.

An n-type semiconductor layer 302 may then be deposited over the p-type semiconductor absorber layer 301. The n-type semiconductor layer 302 may comprise any suitable n-type semiconductor materials, for example, but not limited to ZnS, ZnSe or CdS.

A second electrode 400, also referred to as a transparent top electrode, is further deposited over the n-type semiconductor layer 302. The transparent top electrode 400 may comprise multiple transparent conductive layers, for example, but not limited to, one or more of an Indium Tin Oxide (ITO), Zinc Oxide (ZnO) or Aluminum Zinc Oxide (AZO) layers 402 located over an optional resistive Aluminum Zinc Oxide (RAZO) layer 401. Of course, the transparent top electrode 400 may comprise any other suitable materials, for example, doped ZnO or SnO.

Optionally, one or more antireflection (AR) films (not shown) may be deposited over the transparent top electrode 400, to optimize the light absorption in the cell, and/or current collection grid lines may be deposited over the top conducting oxide.

Alternatively, the solar cell may be formed in reverse order. In this configuration, a transparent electrode is deposited over a substrate, followed by depositing an n-type semiconductor layer over the transparent electrode, depositing at least one p-type semiconductor absorber layer over the n-type semiconductor layer, depositing a first transition metal layer over the at least one p-type semiconductor absorber layer, and optionally depositing a second transition metal layer between the first transition metal layer and the p-type semiconductor absorber layer and/or depositing a alkali diffusion barrier layer over the first transition metal layer. The substrate may be a transparent substrate (e.g., glass) or opaque (e.g., metal). If the substrate used is opaque, then the initial substrate may be delaminated after the steps of depositing the stack of the above described layers, and then bonding a glass or other transparent substrate to the transparent electrode of the stack.

A solar cell described above may be fabricated by any suitable methods. In one embodiment, a method of manufacturing such a solar cell comprises providing a substrate 100, depositing a first electrode 200 over the substrate 100, depositing at least one p-type semiconductor absorber layer 301 over the first electrode 200, depositing an n-type semiconductor layer 302 over the p-type semiconductor absorber layer 301, and depositing a second electrode 400 over the n-type semiconductor layer 302. The step of depositing the first electrode 200 comprises depositing the first transition metal layer 202. While sputtering was described as the preferred method for depositing all layers onto the substrate, some layers may be deposited by MBE, CVD, evaporation, plating, etc. In some embodiments, one or more sputtering steps may be reactive sputtering.

More preferably, the steps of depositing the first electrode 200, depositing the at least one p-type semiconductor absorber layer 301, depositing the n-type semiconductor layer 302, and depositing the second electrode 400 comprise sputtering the alkali-containing transition metal layer 202, the p-type absorber layer 301, the n-type semiconductor layer 302 and one or more conductive films of the second electrode 400 over the substrate 100 (preferably a web substrate in this embodiment) in corresponding process modules of a series of independently isolated, connected process modules without breaking vacuum, while passing the web substrate 100 from an input module to an output module through the series of independently isolated, connected process modules such that the web substrate continuously extends from the input module to the output module while passing through the series of the independently isolated, connected process modules. Each of the process modules may include one or more sputtering targets for sputtering material over the web substrate 100.

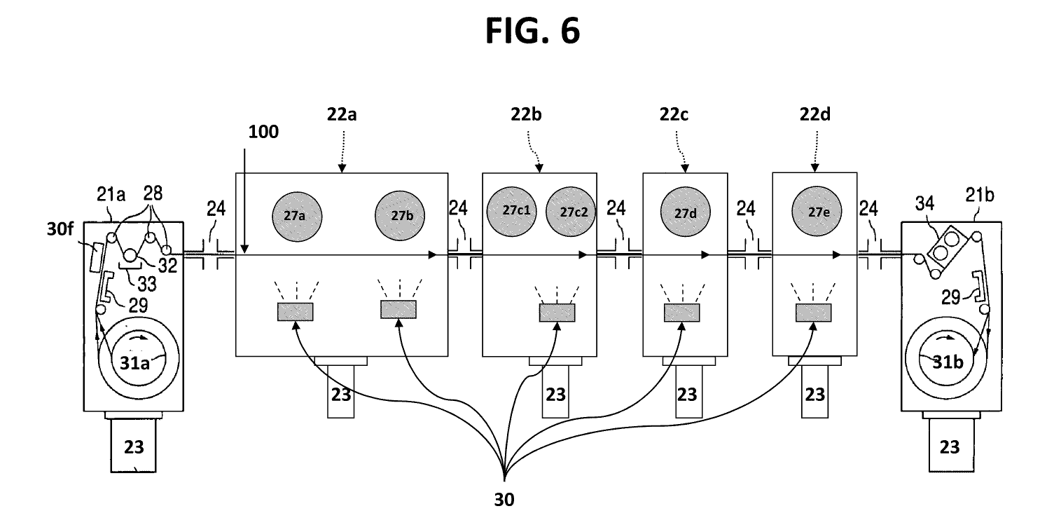

For example, a modular sputtering apparatus for making the solar cell, as illustrated in FIG. 6 (top view), may be used for depositing the layers. The apparatus is equipped with an input, or load, module 21a and a symmetrical output, or unload, module 21b. Between the input and output modules are process modules 22a, 22b, 22c and 22d. The number of process modules 22 may be varied to match the requirements of the device that is being produced. Each module has a pumping device 23, such as vacuum pump, for example a high throughput turbomolecular pump, to provide the required vacuum and to handle the flow of process gases during the sputtering operation. Each module may have a number of pumps placed at other locations selected to provide optimum pumping of process gases. The modules are connected together at slit valves 24, which contain very narrow low conductance isolation slots to prevent process gases from mixing between modules. These slots may be separately pumped if required to increase the isolation even further. Other module connectors 24 may also be used. Alternatively, a single large chamber may be internally segregated to effectively provide the module regions, if desired. U.S. Published Application No. 2005/0109392 A1 (“Hollars”), filed on Oct. 25, 2004, discloses a vacuum sputtering apparatus having connected modules, and is incorporated herein by reference in its entirety for this teaching.

The web substrate 100 is moved throughout the machine by rollers 28, or other devices. Additional guide rollers may be used. Rollers shown in FIG. 6 are schematic and non-limiting examples. Some rollers may be bowed to spread the web, some may move to provide web steering, some may provide web tension feedback to servo controllers, and others may be mere idlers to run the web in desired positions. The input spool 31a and optional output spool 31b thus are actively driven and controlled by feedback signals to keep the web in constant tension throughout the machine. In addition, the input and output modules may each contain a web splicing region or device 29 where the web 100 can be cut and spliced to a leader or trailer section to facilitate loading and unloading of the roll. In some embodiments, the web 100, instead of being rolled up onto output spool 31b, may be sliced into solar modules by the web splicing device 29 in the output module 21b. In these embodiments, the output spool 31b may be omitted. As a non-limiting example, some of the devices/steps may be omitted or replaced by any other suitable devices/steps. For example, bowed rollers and/or steering rollers may be omitted in some embodiments.

Heater arrays 30 are placed in locations where necessary to provide web heating depending upon process requirements. These heaters 30 may be a matrix of high temperature quartz lamps or resistive heating elements laid out across the width of the web. Infrared sensors or thermocouples may provide a feedback signal to servo the heating element power and provide uniform heating across the web. In one embodiment, as shown in FIG. 6, the heaters are placed on one side of the web 100, and sputtering targets 27a-e are placed on the other side of the web 100. Sputtering targets 27 may be mounted on dual cylindrical rotary magnetron(s), or planar magnetron(s) sputtering sources, or RF sputtering sources.

After being pre-cleaned, the web substrate 100 may first pass by heater array 30f in module 21a, which provides at least enough heat to remove surface adsorbed water. Subsequently, the web can pass over roller 32, which can be a special roller configured as a cylindrical rotary magnetron. This allows the surface of electrically conducting (metallic) webs to be continuously cleaned by DC, AC, or RF sputtering as it passes around the roller/magnetron. The sputtered web material is caught on shield 33, which is periodically changed. Preferably, another roller/magnetron may be added (not shown) to clean the back surface of the web 100. Direct sputter cleaning of a web 100 will cause the same electrical bias to be present on the web throughout the machine, which, depending on the particular process involved, might be undesirable in other sections of the machine. The biasing can be avoided by sputter cleaning with linear ion guns instead of magnetrons, or the cleaning could be accomplished in a separate smaller machine prior to loading into this large roll coater. Also, a corona glow discharge treatment could be performed at this position without introducing an electrical bias.

Next, the web 100 passes into the process module 22a through valve 24. Following the direction of the imaginary arrows along the web 100, the full stack of layers may be deposited in one continuous process. The first electrode 202 may be sputtered in the process module 22a over the web 100, as illustrated in FIG. 6. Optionally, the process module 22a may include more than one target, the target comprising an alkali-containing transition metal target 27a, 27b.

Preferably, a lattice distortion element or compound may be contained in at least one sputtering target used for sputtering the first transition metal layer 202. For example, in some embodiments the step of sputtering the first transition metal layer 202 comprises sputtering from a target comprising a combination of the transition metal (e.g., Mo), the alkali element or compound (e.g., Na), and the lattice distortion element or compound (e.g., oxygen or molybdenum oxygen compound), for example, a DC magnetron sodium molybdate target or a composite molybdenum and sodium molybdate target. The composite target may contain 1 to 10 weight percent oxygen, 0.5 to 5 weight percent sodium and balance molybdenum. Additional oxygen may be added to the layer 202 of the solar cell from an oxygen containing ambient in the sputtering chamber if reactive sputtering is used. As discussed above with respect to FIGS. 2 and 3, the MoNa target(s) 27a, 27b initially include a dense molybdenum or another barrier layer, which is removed before the sputter deposition of layer 202 on the substrate 100.

The web 100 then passes into the next process module, 22b, for deposition of the at least one p-type semiconductor absorber layer 301. In a preferred embodiment shown in FIG. 6, the step of depositing the at least one p-type semiconductor absorber layer 301 includes reactively alternating current (AC) magnetron sputtering the semiconductor absorber layer from at least one pair of two conductive targets 27c1 and 27c2, in a sputtering atmosphere that comprises argon gas and a selenium-containing gas. In some embodiment, the pair of two conductive targets 27c1 and 27c2 comprise the same targets. For example, each of the at least two conductive targets 27c1 and 27c2 comprises copper, indium and gallium, or comprises copper, indium and aluminum. The selenium-containing gas may be hydrogen selenide or selenium vapor. In other embodiments, targets 27c1 and 27c2 may comprise different materials from each other. The radiation heaters 30 maintain the web at the required process temperature, for example, around 400-800° C., for example around 500-700° C., which is preferable for the CIS based alloy deposition.

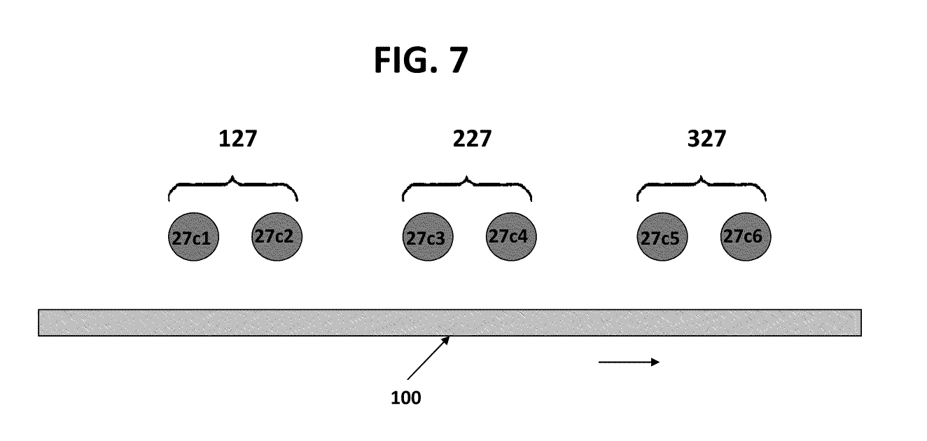

In some embodiments, at least one p-type semiconductor absorber layer 301 may comprise graded CIS based material. In this embodiment, the process module 22b further comprises at least two more pairs of targets (227, and 327), as illustrated in FIG. 7. The first magnetron pair 127 (27c1 and 27c2) are used to sputter a layer of copper indium diselenide while the next two pairs 227, 327 of magnetrons targets (27c3, 27c4 and 27c5, 27c6) sputter deposit layers with increasing amounts of gallium (or aluminum), thus increasing and grading the band gap. The total number of targets pairs may be varied, for example may be 2-10 pairs, such as 3-5 pairs. This will grade the band gap from about 1 eV at the bottom to about 1.3 eV near the top of the layer. Details of depositing the graded CIS material is described in the Hollars published application, which is incorporated herein by reference in its entirety. As discussed above with respect to FIGS. 2 and 3, the CIG targets 27c initially include a dense copper or another barrier layer, which is removed before the sputter deposition of layer 301 on the substrate 100.

Optionally, one or more process modules (not shown) may be added between the process modules 21a and 22a to sputter a back side protective layer over the back side of the substrate 100 before the electrode 200 is deposited on the front side of the substrate. U.S. application Ser. No. 12/379,428 (Attorney Docket No. 075122/0139) titled “Protective Layer for Large-Scale Production of Thin-Film Solar Cells” and filed on Feb. 20, 2009, which is hereby incorporated by reference, describes such deposition process. Further, one or more barrier layers 201 may be sputtered over the front side of the substrate 100 in the process module(s) added between the process modules 21a and 22a. Similarly, one or more process modules (not shown) may be added between the process modules 22a and 22b, to sputter one or more adhesion layers 203 between the alkali-containing transition metal layer 202 and the CIGS layer 301.

The web 100 may then pass into the process modules 22c and 22d, for depositing the n-type semiconductor layer 302, and the transparent top electrode 400, respectively. Any suitable type of sputtering sources may be used, for example, rotating AC magnetrons, RF magnetrons, or planar magnetrons. Extra magnetron stations (not shown), or extra process modules (not shown) could be added for sputtering the optional one or more AR layers.

Finally, the web 100 passes into output module 21b, where it is either wound onto the take up spool 31b, or sliced into solar cells using cutting apparatus 29. While sputtering was described as the preferred method for depositing all layers onto the substrate, some layers may be deposited by MBE, CVD, evaporation, plating, etc., while, preferably, the CIS based alloy is reactively sputtered.

The foregoing method descriptions are provided merely as illustrative examples and are not intended to require or imply that the blocks of the various embodiments must be performed in the order presented. As will be appreciated by one of skill in the art the order of blocks in the foregoing embodiments may be performed in any order. Words such as “thereafter,” “then,” “next,” etc. are not intended to limit the order of the blocks; these words are simply used to guide the reader through the description of the methods. Further, any reference to claim elements in the singular, for example, using the articles “a,” “an,” or “the,” is not to be construed as limiting the element to the singular.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the scope of the invention. Thus, the present invention is not intended to be limited to the embodiments shown herein but is to be accorded the widest scope consistent with the following claims and the principles and novel features disclosed herein.

What is claimed is:

1. A method of making a sputtering target, comprising:
forming a sputtering target comprising a sputtering material that is substantially free of all of at least one of absorbed or adsorbed water; and
forming a water impermeable barrier layer over the sputtering material to completely or substantially prevent at least one of re-absorption or re-adsorption of water to the sputtering material.

2. The method of claim 1, wherein the sputtering material comprises a metal and the barrier layer is selected from the group consisting of a metal, a ceramic and a polymer.

3. The method of claim 2, wherein the sputtering material comprises sodium molybdate and the barrier layer comprises a molybdenum layer having a higher density than the sputtering material, or the sputtering material comprises CIG and the barrier layer comprises a copper layer having a higher density than the sputtering material.

4. The method of claim 1, wherein the step of forming the sputtering target comprises:
(i) forming the sputtering target having the sputtering material that is initially substantially free of all of at least one of absorbed or adsorbed water; or
(ii) treating the sputtering target to remove substantially all of at least one of absorbed or adsorbed water from the sputtering material prior to the step of forming the water impermeable barrier layer.

5. The method of claim 4, wherein the step of treating the sputtering target comprises heating the sputtering target to at least 200 C to remove at least 95% of at least one of absorbed and adsorbed water in the sputtering material.

6. The method of claim 1, further comprising placing the sputtering target comprising the barrier layer into a sputtering chamber and removing the barrier layer in the sputtering chamber.

7. The method of claim 6, wherein the barrier layer is removed by at least one of a bake out and a burn-in process.

8. The method of claim 1, further comprising removing the barrier layer and placing the sputtering target with the barrier layer removed into a sputtering chamber without exposing the target to a water containing ambient that increases a moisture content of the sputtering material by more than 10 weight percent of its fully saturated water weight.

9. The method of claim 8, wherein the barrier layer is removed by at least one of etching, ashing, heating, cooling, thermal shock, spraying with dry ice, and abrasion; and the sputtering target is provided from a location of the barrier layer removal into the sputtering chamber in an inert ambient or in a vacuum.

10. A method of using a sputtering target, comprising:
providing a sputtering target comprising a sputtering material having substantially no absorbed or adsorbed water in the sputtering material and comprising a water impermeable barrier layer over the sputtering material;
removing the barrier layer; and
providing the sputtering target into a sputtering chamber such that the sputtering material in the sputtering chamber is completely or substantially water free.

11. The method of claim 10, wherein:
the step of removing the barrier layer occurs after the step of providing the sputtering target into the sputtering chamber;
the step of providing the sputtering target into a sputtering chamber comprises placing the sputtering target comprising the barrier layer into the sputtering chamber; and
the step of removing the barrier layer occurs in the sputtering chamber.

12. The method of claim 11, wherein the step of removing the barrier layer comprises at least one of a bake out and a burn-in process in the sputtering chamber.

13. The method of claim 10, wherein:
the step of removing the barrier layer occurs before the step of providing the sputtering target into the sputtering chamber;
the step of removing the barrier layer occurs outside the sputtering chamber; and
the step of providing the sputtering target into a sputtering chamber comprises placing the sputtering target with the barrier layer removed into the sputtering chamber without exposing the target to a water containing ambient that increases a moisture content of the sputtering material by more than 10 weight percent of its fully saturated water weight.

14. The method of claim 13, wherein the step of removing the barrier layer comprises at least one of etching, ashing, heating, cooling, thermal shock, spraying with dry ice, and abrasion; and the step of providing the sputtering target into a sputtering chamber comprises providing the sputtering target from a location of the barrier layer removal into the sputtering chamber in an inert ambient or in a vacuum.

15. The method of claim 10, wherein the sputtering material comprises a metal and the barrier layer is selected from the group consisting of a metal, a ceramic and a polymer.

16. The method of claim 15, wherein the sputtering material comprises sodium molybdate and the barrier layer comprises a molybdenum layer having a higher density than the sputtering material.

17. The method of claim 16, further comprising:
providing a substrate;
depositing a first electrode over the substrate wherein the first electrode comprises sodium and oxygen containing molybdenum layer formed by sputtering the sodium molybdate sputtering material from the sputtering target;
depositing at least one p-type semiconductor absorber layer over the first electrode, wherein the p-type semiconductor absorber layer includes a copper indium selenide (CIS) based alloy material;
depositing an n-type semiconductor layer over the p-type semiconductor absorber layer; and
depositing a second electrode over the n-type semiconductor layer to form a solar cell.

18. The method of claim 17, wherein:
the p-type semiconductor absorber layer comprises 0.005 to 1.5 atomic percent sodium diffused from the sodium and oxygen containing molybdenum layer;
the sodium and oxygen containing molybdenum layer comprises at least 59 atomic percent molybdenum, 5 to 40 atomic percent oxygen and 0.01 to 1.5 atomic percent sodium; and
the step of depositing the first electrode comprises:
depositing an alkali diffusion barrier layer over the substrate;
depositing the sodium and oxygen containing molybdenum layer over the alkali diffusion barrier layer; and
depositing a second transition metal layer over the sodium and oxygen containing molybdenum layer and under the p-type semiconductor absorber layer.

19. The method of claim 15, wherein the sputtering material comprises CIG and the barrier layer comprises a copper layer having a higher density than the sputtering material.

20. The method of claim 10, wherein the sputtering material has a porosity of 7-25 volume percent, the barrier layer has a porosity of 2 volume percent or less, and the sputtering material contains less than 0.1 atomic percent absorbed or absorbed water.

21. A sputtering target, comprising a sputtering material having substantially no absorbed or adsorbed water in the sputtering material and a water impermeable barrier layer over the sputtering material having a higher density than the sputtering material.

22. The target of claim 21, wherein the sputtering material has a porosity of 7-25 volume percent, the bather layer has a porosity of 2 volume percent or less, and the sputtering material contains less than 0.1 atomic percent absorbed or absorbed water.

23. The target of claim 21, wherein the sputtering material comprises sodium molybdate and the barrier layer comprises a molybdenum layer.

24. The target of claim 21, wherein the sputtering material comprises CIG and the barrier layer comprises a copper layer.
